(19) United States
(12) Patent Application Publication
(10) Pub. No.: US 2015/0091168 A1
(43) Pub. Date: Apr. 2, 2015

(54) MULTI-CHIP PACKAGE

(71) Applicant: Samsung Electronics Co., Ltd., Suwon-Si (KR)

(72) Inventor: Keun-Ho CHOI, Asan-si (KR)

(21) Appl. No.: 14/327,710

(22) Filed: Jul. 10, 2014

(30) Foreign Application Priority Data
Oct. 2, 2013 (KR) 10-2013-0117630

(51) Int. Cl. H01L 23/00; H01L 23/498; H01L 25/065

(52) U.S. Cl. CPC H01L 24/06; H01L 25/0657; H01L 23/49816; H01L 2224/0605
USPC 257/738

(57) ABSTRACT

A multi-chip package may include a bonding finger. The bonding finger may have a bonding portion having a wide width so that lower ends of conductive wires may be accurately connected to the wide bonding portion. Thus, an electrical connection between a package substrate and semiconductor chips may be improved.

### CROSS-RELATED APPLICATION

This application claims priority under 35 USC §119 from Korean Patent Application No. 2013-0117630, filed on Oct. 2, 2013, in the Korean Intellectual Property Office (KIPO), the contents of which are herein incorporated by reference in their entirety.

### BACKGROUND

1. Field

Example embodiments relate to a multi-chip package. More particularly, example embodiments relate to a multi-chip package including sequentially stacked semiconductor chips.

2. Description of the Related Art

Generally, various semiconductor fabrication processes may be performed on a semiconductor substrate to form a plurality of semiconductor chips. In order to mount the semiconductor chips on a printed circuit board (PCB), a packaging process may be performed on the semiconductor chip to form a semiconductor package.

In order to increase storage capacity of the semiconductor package, a multi-chip package including the sequentially stacked semiconductor chips may be widely developed. The multi-chip package may include a package substrate, the semiconductor chips sequentially stacked on the package substrate, and conductive wires electrically connected between the semiconductor chips and the package substrate. The package substrate may have bonding fingers to which the conductive wires may be connected.

According to related art, an upper conductive wire extending from an upper semiconductor chip, and a lower conductive wire extending from a lower semiconductor chip, may be electrically connected to any one of the bonding fingers. Thus, the upper conductive wire may be placed on the lower conductive wire. That is, the conductive wires may be stacked on a single bonding finger.

However, because the bonding finger may have a narrow width, the conductive wires may not be accurately connected to the narrow bonding finger. Therefore, the semiconductor chips may be disconnected from the package substrate.

### SUMMARY

At least one example embodiment relates to a multi-chip package having improved electrical connection between semiconductor chips and/or a package substrate.

At least one example embodiment includes a multi-chip package. The multi-chip package may include a package substrate, a first semiconductor chip, a first conductive wire, a second semiconductor chip and a second conductive wire. The package substrate may have bonding fingers arranged on an upper surface of the package substrate. Each of the bonding fingers may have a body portion and a bonding portion having a width greater than the width of the body portion. The first semiconductor chip may be arranged on the upper surface of the package substrate. The first semiconductor chip may have first bonding pads. The first conductive wire may have a first end connected to the first bonding pads, and a second end connected to the bonding portion of the bonding finger. The second semiconductor chip may be arranged on an upper surface of the first semiconductor chip. The second semiconductor chip may have second bonding pads. The second conductive wire may have a first end connected to the second bonding pads, and a second end connected to the second end of the first conductive wire.

In example embodiments, the bonding portion may have a rectangular shape.

In example embodiments, the bonding portions of the bonding fingers may be arranged in a first direction substantially the same as an arrangement direction of the first and second bonding pads.

In example embodiments, the bonding portions of the bonding fingers may be arranged in a zigzag pattern along a first direction substantially the same as an arrangement direction of the first and second bonding pads.

In example embodiments, the adjacent bonding portions among the bonding portions may have side surfaces opposite to each other in the first direction. The opposite side surfaces may be substantially parallel to a second direction substantially perpendicular to the first direction.

In example embodiments, the opposite side surfaces of the adjacent bonding portions may be partially overlapped with each other in the second direction.

In example embodiments, the opposite side surfaces of the adjacent bonding portions may be spaced apart from each other in the first direction.

In example embodiments, the second end of the first conductive wire may have a stitching portion.

In example embodiments, the second end of the second conductive wire may have a bump portion connected to the stitching portion.

In example embodiments, the package substrate may further include ball terminals arranged on a lower surface of the package substrate. The ball terminals may be electrically connected to the body portions of the bonding fingers.

In example embodiments, the multi-chip package may further include external terminals mounted on the ball terminals.

In example embodiments, the multi-chip package may further include a molding member formed on the upper surface of the package substrate to cover the first semiconductor chip and the second semiconductor chip.

In example embodiments, the first semiconductor chip and the second semiconductor chip may have side surfaces positioned on a vertical plane.

In example embodiments, the first semiconductor chip and the second semiconductor chip may be stacked in a step-like configuration.

At least one example embodiment includes a multi-chip package. The multi-chip package may include a package substrate, a first semiconductor chip, a first conductive wire, a second semiconductor chip, a second conductive wire, a molding member and external terminals. The package substrate may have bonding fingers arranged on an upper surface of the package substrate, and ball terminals arranged on a lower surface of the package substrate. Each of the bonding fingers may have a body portion and a bonding portion having a width greater than the width of the body portion. The first semiconductor chip may be arranged on the upper surface of the package substrate. The first semiconductor chip may have first bonding pads. The first conductive wire may have a first end connected to the first bonding pads, and a second end connected to the bonding portion of the bonding finger. The second semiconductor chip may be arranged on an upper surface of the first semiconductor chip. The second semiconductor chip may have second bonding pads. The second conductive wire may have a first end connected to the second bonding pads, and a second end connected to the second end of the first conductive wire. The molding member may be formed on the upper surface of the package substrate to cover the first semiconductor chip and the second semiconductor chip. The external terminals may be mounted on the ball terminals.

According to at least one example embodiment, the bonding portion of the bonding finger may have a large width so that the lower ends of the conductive wires may be accurately connected to the wide bonding portion. Thus, an electrical connection between the package substrate and the semiconductor chips may be improved.

At least one example embodiment relates to a multi-chip package including a package substrate having a plurality of bonding fingers on an upper surface thereof, each of the bonding fingers including a body portion and a bonding portion, a first semiconductor chip on the upper surface of the package substrate, the first semiconductor chip including a plurality of first bonding pads, at least one of the first bonding pads being connected to a first end of a first conductive wire, a second end of the first conductive wire including a stitching portion coupled to at least one of the bonding portions, and a second semiconductor chip on an upper surface of the first semiconductor chip, the second semiconductor chip including a plurality of second bonding pads, at least one of the second bonding pads being connected to a first end of a second conductive wire, a second end of the second conductive wire including a bump portion coupled to the stitching portion.

### BRIEF DESCRIPTION OF THE DRAWINGS

At least one example embodiment will be more clearly understood from the following detailed description taken in conjunction with the accompanying drawings. FIGS. 1 to 7 represent non-limiting, example embodiments as described herein.

FIG. 1 is across-sectional view illustrating a multi-chip package in accordance with at least one example embodiment;

FIG. 2 is a plan view illustrating the multi-chip package in FIG. 1;

FIG. 3 is an enlarged cross-sectional view of a portion “III” in FIG. 1;

FIG. 4 is a cross-sectional view illustrating a multi-chip package in accordance with at least one example embodiment;

FIG. 5 is a plan view illustrating the multi-chip package in FIG. 4;

FIG. 6 is a plan view illustrating a multi-chip package in accordance with at least one example embodiment; and

FIG. 7 is a cross-sectional view illustrating a multi-chip package in accordance with at least one example embodiment.

### DETAILED DESCRIPTION OF THE EMBODIMENTS

At least one example embodiment will be described more fully hereinafter with reference to the accompanying drawings, in which some example embodiments are shown. The example embodiments may, however, be embodied in many different forms and should not be construed as limited to the examples set forth herein. Rather, these example embodiments are provided so that this disclosure will be thorough and complete, and will fully convey the scope of the disclosure to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the example embodiments.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

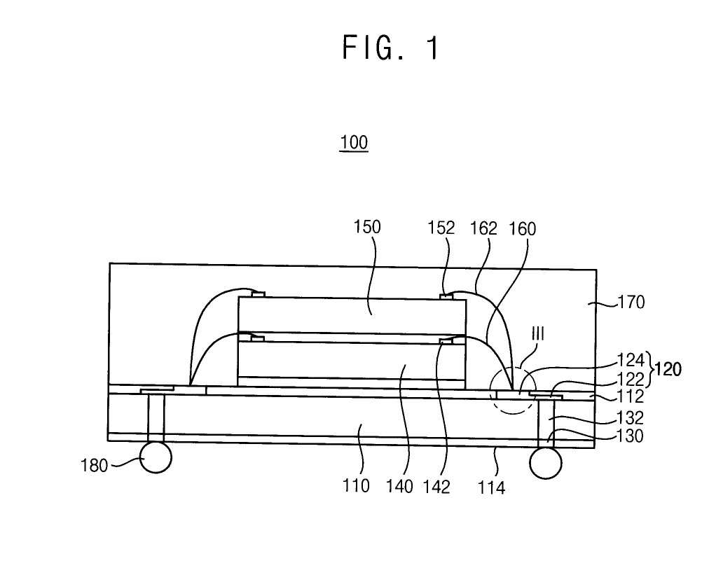

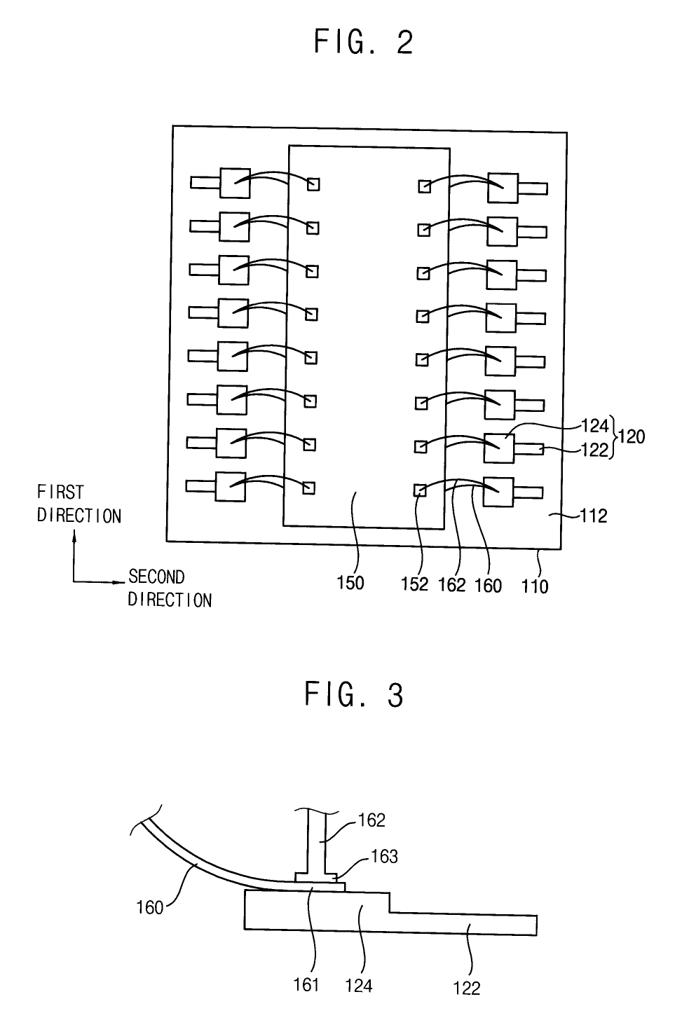

FIG. 1 is a cross-sectional view illustrating a multi-chip package in accordance with at least one example embodiment, FIG. 2 is a plan view illustrating the multi-chip package in FIG. 1, and FIG. 3 is an enlarged cross-sectional view of a portion “III” in FIG. 1.

Referring to FIG. 1, a multi-chip package 100 of this example embodiment may include a package substrate 110, a first semiconductor chip 140, a second semiconductor chip 150, a first conductive wire 160, a second conductive wire 162, a molding member 170 and external terminals 180.

Referring to FIGS. 1 and 2, the package substrate 110 may include bonding fingers 120, a first insulating layer 112, a second insulating layer 114, ball terminals 130 and contact plugs 132.

The bonding fingers 120 may be arranged on an upper surface of the package substrate 110. In example embodiments, each of the bonding fingers 120 may include a body portion 122 and a bonding portion 124. The body portions 122 may be arranged on both edge portions of the upper surface of the package substrate 110. The body portions 122 may extend in a second direction. The bonding portion 124 may extend from an inner end of the body portion 122. The bonding portion 124 may have a width greater than the width of the body portion 122. In example embodiments, the bonding portion 124 may have a rectangular shape. The bonding portions 124 may be arranged in a first direction substantially perpendicular to the second direction.

The first insulating layer 112 may be formed on the upper surface of the package substrate 110. The first insulating layer 112 may have openings configured to expose the bonding portions 124. The first insulating layer 112 may have a shape configured to cover the body portions 122. In example embodiments, the first insulating layer 112 may be configured to fully or partially cover the body portions 122.

The ball terminals 130 may be arranged on a lower surface of the package substrate 110. The second insulating layer 114 may be formed on the lower surface of the package substrate 110. The second insulating layer 114 may have openings configured to expose the ball terminals 130. The contact plugs 132 may be vertically formed in the package substrate 110. The contact plugs 132 may electrically connect the body portions 122 of the bonding fingers 120 with the ball terminals 130.

The first semiconductor chip 140 may be arranged on the upper surface of the package substrate 110. The first semiconductor chip 140 may have first bonding pads 142. In example embodiments, the first bonding pads 142 may be arranged on both edge portions of an upper surface of the first semiconductor chip 140 in the first direction. Thus, the arrangement direction of the first bonding pads 142 may be substantially the same as the arrangement direction of the bonding portions 124.

The second semiconductor chip 150 may be arranged on an upper surface of the first semiconductor chip 140. The second semiconductor chip 150 may have second bonding pads 152. In example embodiments, the second bonding pads 152 may be arranged on both edge portions of an upper surface of the second semiconductor chip 150 in the first direction. Thus, the arrangement direction of the second bonding pads 152 may be substantially the same as the arrangement direction of the bonding portions 124.

In example embodiments, the first semiconductor chip 140 and the second semiconductor chip 150 may be vertically stacked. Further, the first semiconductor chip 140 may have a size substantially the same as the size of the second semiconductor chip 150. Therefore, the first semiconductor chip 140 may have a side surface substantially coplanar with the side surface of the second semiconductor chip 150. The second semiconductor chip 150 may cover the first bonding pads 142 so that the first bonding pads 142 may not be exposed.

The first conductive wire 160 may be electrically connected between the first semiconductor chip 140 and the package substrate 110. In example embodiments, the first conductive wire 160 may have a first end connected to the first bonding pad 142 of the first semiconductor chip 140, and a second end connected to the bonding portion 124 of the bonding finger 120. As mentioned above, because the width of the bonding portion 124 may be wider than the width of the body portion 122, the second end of the first conductive wire 160 may be accurately connected to the bonding portion 124.

The second conductive wire 162 may be electrically connected between the second semiconductor chip 150 and the package substrate 110. In example embodiments, the second conductive wire 162 may have a first end connected to the second bonding pad 152 of the second semiconductor chip 150, and a second end connected to the second end of the first conductive wire 160. In example embodiments, the second end of the second conductive wire 162 may be overlapped with the second end of the first conductive wire 160. Thus, the second conductive wire 160 may be electrically connected with the bonding portion 124 via the first conductive wire 160. Therefore, the second ends of both the first conductive wire 160 and the second conductive wire 162 may be connected together with the single bonding portion 124.

Referring to FIG. 3, the second end of the first conductive wire 160 may have a stitching portion 161, according to at least one example embodiment. The stitching portion 161 may be bonded to the bonding portion 124. The second end of the second conductive wire 162 may have a bump portion 163 having an area larger than the area of the stitching portion 161. The bump portion 163 may be bonded to the stitching portion 161.

Referring again to FIG. 1, the molding member 170 may be formed on the upper surface of the package substrate 110 to cover the first semiconductor chip 140, the second semiconductor chip 150, the first conductive wire 160 and the second conductive wire 162. The molding member 170 may protect the first semiconductor chip 140, the second semiconductor chip 150, the first conductive wire 160 and the second conductive wire 162 from the external environment. In example embodiments, the molding member 170 may include an epoxy molding compound (EMC).

The external terminals 180 may be mounted on the ball terminals 130 of the package substrate 110. In example embodiments, the external terminals 180 may include solder balls.

According to at least this example embodiment, the width of the bonding portion 124 may be wider than the width of the body portion 122 so that the lower ends of the conductive wires 160 and 162 may be accurately connected to the wide bonding portion 124. Thus, an electrical connection between the package substrate and the semiconductor chips may be improved.

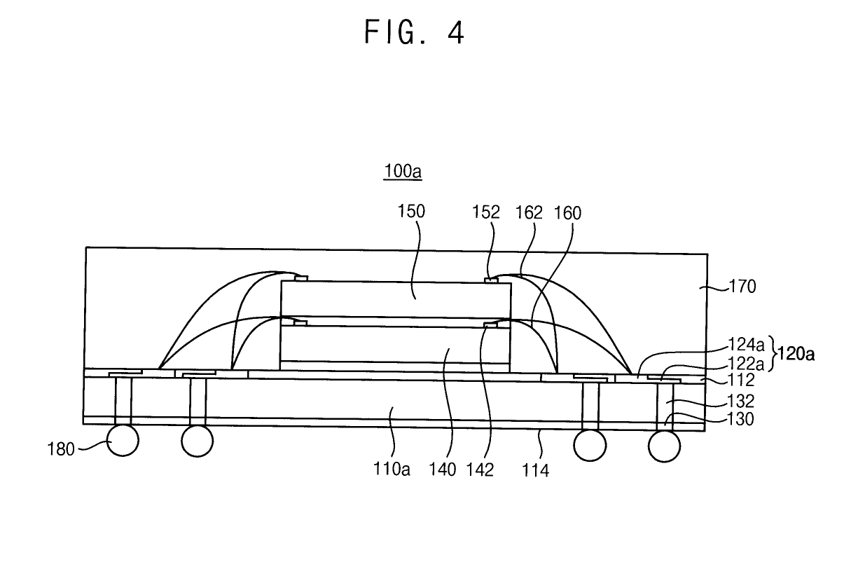

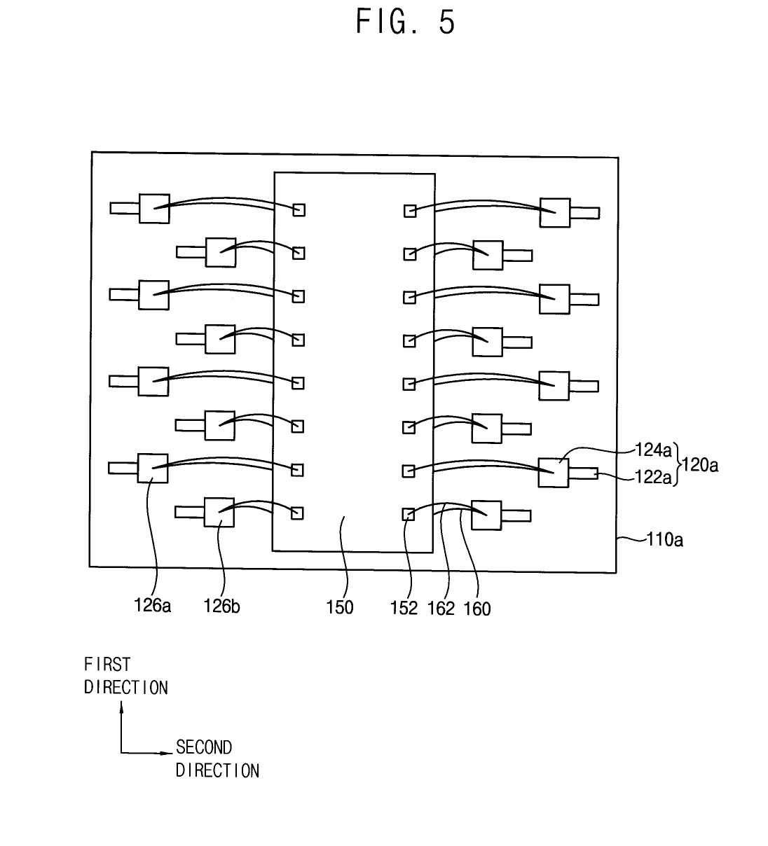

FIG. 4 is a cross-sectional view illustrating a multi-chip package in accordance with at least one example embodiment, and FIG. 5 is a plan view illustrating the example multi-chip package in FIG. 4.

A multi-chip package 100a of this example embodiment may include elements substantially the same as the elements of the multi-chip package 100 in FIG. 1 except for the bonding finger. Thus, the same reference numerals may refer to the same elements and any further illustrations with respect to the same elements may be omitted herein for brevity.

Referring to FIGS. 4 and 5, a package substrate 110a of this example embodiment may include bonding fingers 120a. Each of the bonding fingers 120a may include a body portion 122a and a bonding portion 124a. The bonding portions 124a may be arranged in a zigzag or alternating pattern along the first direction. Thus, odd-numbered bonding portions 124a may be positioned adjacent to the second bonding pads 152. In contrast, even-numbered bonding portions 124a may be positioned further from the second bonding pads 152. As a result, the second conductive wires 162 connected to the odd-numbered bonding portions 124a may have a shorter length than the length of the second conductive wires 162 connected to the even-numbered bonding portions 124a.

In example embodiments, the odd-numbered bonding portions 124a and the even-numbered bonding portions 124a may have side surfaces 126a and 126b, respectively, opposite to each other in the first direction. The opposite side surfaces 126a and 126b of the bonding portions 124a may be spaced apart from each other in the first direction.

According to at least this example embodiment, because the bonding portions may be arranged in the zigzag or alternated pattern, the adjacent bonding portions may have a width gap. Thus, the bonding portions may have a sufficiently large width so that the conductive wires 160 and 162 may be more accurately connected to the wide bonding portions.

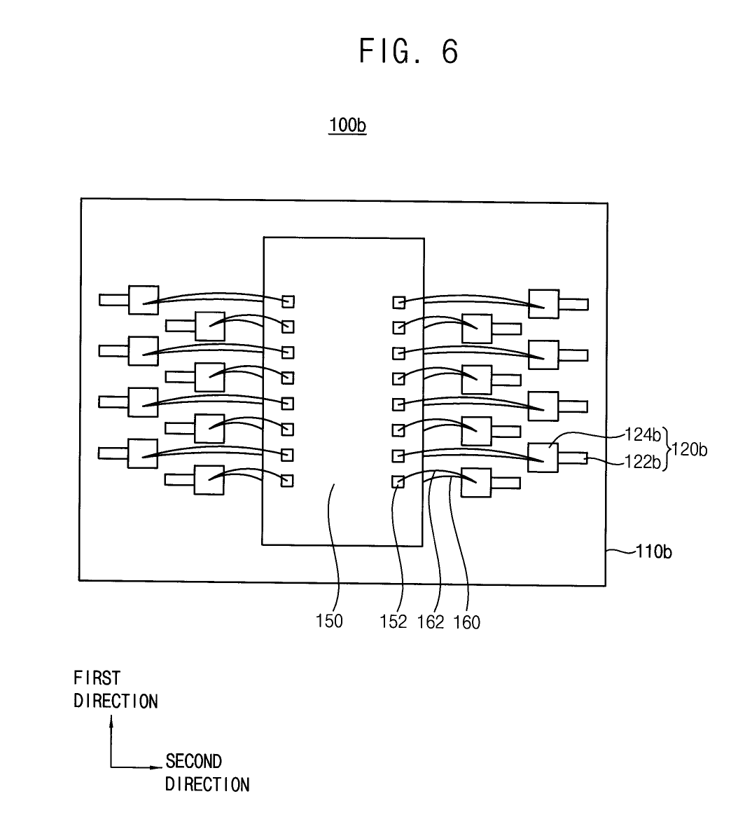

FIG. 6 is a plan view illustrating a multi-chip package in accordance with at least one example embodiment.

A multi-chip package 100b of this example embodiment may include elements substantially the same as those of the multi-chip package 100a in FIG. 4 except for a bonding finger. Thus, the same reference numerals may refer to the same elements and any further illustrations with respect to the same elements may be omitted herein for brevity.

Referring to FIG. 6, a package substrate 110b of this example embodiment may include bonding fingers 120b. Each of the bonding fingers 120b may include a body portion 122b and a bonding portion 124b. The bonding portions 124b may be arranged in a zigzag or alternating pattern along the first direction. In example embodiments, the opposite side surfaces 126a and 126b of the bonding portions 124b may be partially overlapped with each other in the first direction.

According to this example embodiment, because the zigzag-arranged bonding portions may be partially overlapped with each other in the first direction, the bonding portions may occupy a smaller area on the upper surface of the package substrate than the area of the bonding portions illustrated in FIG. 5. Therefore, the multi-chip package may have a small size with an improved electrical connection between the conductive wires 160 and 162 and the bonding finger 120b.

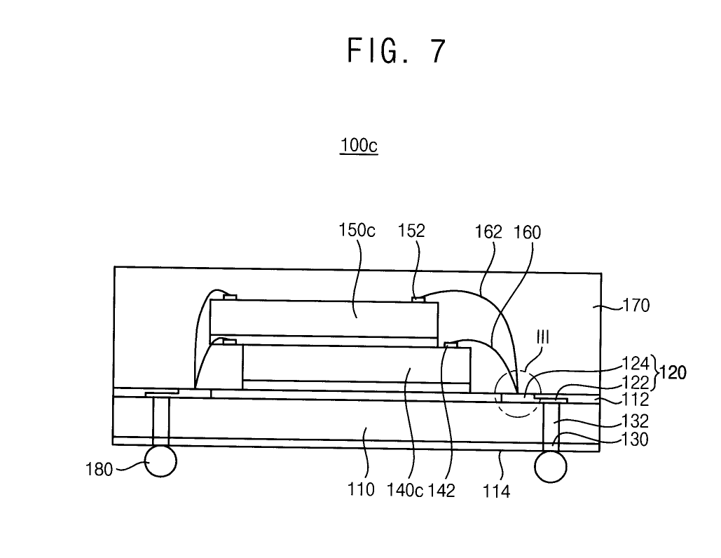

FIG. 7 is a cross-sectional view illustrating a multi-chip package in accordance with at least one example embodiment.

A multi-chip package 100c of this example embodiment may include elements arranged substantially the same as those of the multi-chip package 100 in FIG. 1 except for semiconductor chips. Thus, the same reference numerals may refer to the same elements and any further illustrations with respect to the same elements may be omitted herein for brevity.

Referring to FIG. 7, a multi-chip package 100c of this example embodiment may include a first semiconductor chip 140c and a second semiconductor chip 150c. In example embodiments, the first semiconductor chip 140c and the second semiconductor chip 150c may be stacked in a step-like configuration. Thus, the second semiconductor chip 150c may not cover the first bonding pads 142 so that the first bonding pads 142 may be upwardly exposed.

Alternatively, the multi-chip package 100c may include the package substrate 110a in FIG. 4 or the package substrate 110b in FIG. 6.

In example embodiments, the multi-chip packages may include the two semiconductor chips 140c and 150c. Alternatively, the multi-chip package may include at least three semiconductor chips. For example, when a third semiconductor chip may be stacked on the second semiconductor chip 150c. a third conductive wire may be electrically connected between the bonding portion of the bonding finger and a third bonding pad of the third semiconductor chip. Further, because the lower end of the second conductive wire may have a bump portion, a lower end of the third conductive wire, which may be connected to the bump portion of the second conductive wire, may have a stitching portion similar to, or the same as, the configuration illustrated in FIG. 3.

According to example embodiments, the bonding finger may have a bonding portion with a large width so that the lower ends of the conductive wires 160 and 162 may be accurately connected to the wide bonding portion. Thus, an electrical connection between the package substrate and the semiconductor chips may be improved.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages. Accordingly, all such modifications are intended to be included within the current scope as defined in the claims. It is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A multi-chip package comprising:
a package substrate having a plurality of bonding fingers on an upper surface thereof, each of the bonding fingers including a body portion and a bonding portion, the bonding portion having a width greater than a width of the body portion;
a first semiconductor chip on the upper surface of the package substrate, the first semiconductor chip including a plurality of first bonding pads;
a first conductive wire having a first end connected to at least one of the first bonding pads, and a second end connected to at least one of the bonding portions;
a second semiconductor chip on an upper surface of the first semiconductor chip, the second semiconductor chip including a plurality of second bonding pads; and
a second conductive wire having a first end connected to at least one of the second bonding pads, and a second end connected to the second end of the first conductive wire.

2. The multi-chip package of claim 1, wherein at least one of the bonding portions has a rectangular shape.

3. The multi-chip package of claim 1, wherein the bonding portions are arranged in a first direction substantially parallel to an arrangement direction of the first and second bonding pads.

4. The multi-chip package of claim 1, wherein the bonding portions are arranged in an alternating pattern along a first direction substantially parallel to an arrangement direction of the first and second bonding pads.

5. The multi-chip package of claim 4, wherein adjacent bonding portions have side surfaces that are opposite to each other in the first direction, and the opposite side surfaces are arranged along a second direction substantially perpendicular to the first direction.

6. The multi-chip package of claim 5, wherein the opposite side surfaces of the bonding portions are partially overlapped with each other in the second direction.

7. The multi-chip package of claim 5, wherein the opposite side surfaces of the bonding portions are spaced apart from each other in the first direction.

8. The multi-chip package of claim 1, wherein the second end of the first conductive wire comprises a stitching portion.

9. The multi-chip package of claim 8, wherein the second end of the second conductive wire comprises a bump portion connected to the stitching portion of the first conductive wire.

10. The multi-chip package of claim 1, wherein the package substrate further comprises ball terminals on a lower surface of the package substrate and electrically connected to at least one of the body portions.

11. The multi-chip package of claim 10, further comprising external terminals mounted on the ball terminals.

12. The multi-chip package of claim 1, further comprising a molding member on the upper surface of the package substrate and covering the first semiconductor chip and the second semiconductor chip.

13. The multi-chip package of claim 1, wherein the first semiconductor chip has a side surface substantially coplanar with a side surface of the second semiconductor chip.

14. The multi-chip package of claim 1, wherein the first semiconductor chip and the second semiconductor chip are stacked in a step-like configuration.

15. A multi-chip package comprising:
a package substrate having a plurality of bonding fingers on an upper surface thereof and ball terminals on a lower surface of the package substrate, each of the bonding fingers including a body portion and a bonding portion, the bonding portion having a width greater than a width of the body portion;
a first semiconductor chip arranged on the upper surface of the package substrate, the first semiconductor chip including a plurality of first bonding pads;
a first conductive wire having a first end connected to at least one of the first bonding pads, and a second end connected to at least one of the bonding portions;
a second semiconductor chip on an upper surface of the first semiconductor chip, the second semiconductor chip including a plurality of second bonding pads;
a second conductive wire having a first end connected to at least one of the second bonding pads, and a second end connected to the second end of the first conductive wire;
a molding member on the upper surface of the package substrate and covering the first semiconductor chip and the second semiconductor chip; and
external terminals mounted on the ball terminals.

16. A multi-chip package comprising:
a package substrate having a plurality of bonding fingers on an upper surface thereof, each of the bonding fingers including a body portion and a bonding portion;
a first semiconductor chip on the upper surface of the package substrate, the first semiconductor chip including a plurality of first bonding pads, at least one of the first bonding pads being connected to a first end of a first conductive wire, a second end of the first conductive wire including a stitching portion coupled to at least one of the bonding portions; and
a second semiconductor chip on an upper surface of the first semiconductor chip, the second semiconductor chip including a plurality of second bonding pads, at least one of the second bonding pads being connected to a first end of a second conductive wire, a second end of the second conductive wire including a bump portion coupled to the stitching portion.

17. The multi-chip package of claim 16, wherein a surface area of the bump portion is greater than a surface area of the stitching portion.

18. The multi-chip package of claim 16, wherein a width of the bonding portion is greater than a width of the body portion in at least one of the bonding fingers.

19. The multi-chip package of claim 16, wherein one of:
the first semiconductor chip and the second semiconductor chip are in a step-like configuration; and
a side surface of the first semiconductor chip is substantially coplanar with a side surface of the second semiconductor chip.

20. The multi-chip package of claim 16, wherein:
the plurality of bonding portions are arranged in an alternating pattern along a first direction substantially parallel to an arrangement direction of the first and second bonding pads; and
a length of one of the first and second conductive wires connected to a first bonding portion is greater than a length of another one of the first and second conductive wires connected to a second bonding portion adjacent to the first bonding portion.
